(19) United States
(12) Patent Application Publication
(10) Pub. No.: US 2022/0321038 A1
(43) Pub. Date: Oct. 6, 2022

(54) ROTATING DEVICE

(71) Applicant: MINEBEA MITSUMI Inc., Nagano (JP)

(72) Inventors: Kazuo TAKADA, Kosai-shi (JP); Haruka MIYAJI, Toyohashi-shi (JP); Azusa IKEGAMI, Fukuroi-shi (JP)

(21) Appl. No.: 17/656,701

(22) Filed: Mar. 28, 2022

(30) Foreign Application Priority Data
Mar. 31, 2021 (JP) 2021-061571

(51) Int. Cl. H02P 8/34; H02K 7/116; H02K 11/30; H02K 37/24

(52) U.S. Cl. CPC H02P 8/34; H02K 7/116; H02K 11/30; H02K 37/24

(57) ABSTRACT

The application includes a rotating device 1 that includes a variable resistor, a voltage output line configured to output a voltage, and an adjustment resistor. A resistance value Rx of the adjustment resistor is set to a value between a minimum value RxMin determined in a manner for a ratio of an adjustment voltage Vx in a case of having the adjustment resistor to a reference voltage Vo in a case of not having the adjustment resistor to become greater than or equal to a predetermined value, and a maximum value RxMax determined in a manner for noise generated on the voltage output from the voltage output line with the contact position located within a dead zone of a position sensor 80 to become less than or equal to a predetermined value.

### CROSS-REFERENCE TO RELATED APPLICATIONS

This application claims the benefit of priority to Japanese Application No. 2021-061571, filed Mar. 31, 2021, the entire disclosure of which is hereby incorporated herein by reference.

### TECHNICAL FIELD

The present invention relates to a rotating device.

### BACKGROUND ART

A rotating device such as that described in Patent Literature 1 has been known as a rotating device used as a so-called actuator. The above rotating device includes an output gear, a motor configured to drive the output gear, and a housing having an opening formed to communicate with the outside at a position corresponding to the output gear, thus making it possible to access the output gear from the outside of the housing through the opening.

### CITATION LIST

### Patent Literature

Patent Literature 1: JP 2018-038250 A

### SUMMARY OF INVENTION

### Technical Problem

In the above-described rotating device, the output gear is driven and controlled using a stepping motor. In other words, the output gear is controlled to be driven to a target position by rotating the stepping motor until the number of drive signal pulses of the stepping motor reaches the pulse count of the movement target. A rotating device using a stepping motor has high position control accuracy, and thus fine control is possible to be made.

However, a rotating device using a stepping motor does not have physical position information of the output gear, and therefore, when rotational abnormality of the output gear (for example, idling of the output gear) occurs due to breakage of the gear or the like, there exists no measure for detecting the abnormality.

As a drive control scheme for a rotating device, a scheme for feedback control by a voltage detected by a potentiometer attached to a rotating mechanism is known in addition to a scheme for open loop control using a stepping motor as described above.

In a rotating device using feedback by the potentiometer, a voltage changing in accordance with the rotation of the output gear is detected by the potentiometer, the current position of the output gear is specified from the detected voltage, and a drive amount is fed back from the specified current position, whereby the output gear is driven and controlled to be moved to the target position. In the rotating device using feedback by the potentiometer, a physical current position of the output gear is said to be ascertained.

However, in the rotating device using feedback by a potentiometer, the accuracy of position control is largely dependent on the performance of the potentiometer. In order to enhance the accuracy of position control, like a stepping motor, in the rotating device using feedback by the potentiometer, it is necessary, for example, to increase the detection sensitivity of the potentiometer and also to prepare an IC with a highly sensitive property, thus possibly complicating the structure.

In addition, in a rotating device using rotation position detection using a position sensor such as a potentiometer, there exists a dead zone, and in this dead zone, position information cannot be acquired within a range of one turn of the position sensor. When processing utilizing the position information acquired by using such position sensor is performed, accurate processing is difficult to be performed when the rotation position of the output gear is located within the dead zone. In this dead zone, it is difficult to detect the rotation position by the position sensor. For example, when processing is performed to detect abnormality of the output gear rotation by making use of position information obtained by the potentiometer, it is difficult to accurately detect the abnormality in a state of the rotation position of the output gear being located within the dead zone of the potentiometer. In the device described above, a problem is its narrow movable range due to exclusion of the dead zone from the movable range.

In order to deal with the problem of the narrow movable range, the following is conceivable: it is determined whether or not the rotation position of the output gear is located within the dead zone of the position sensor, and when it is determined that the rotation position of the output gear is located within the dead zone of the position sensor, processing corresponding to the dead zone is executed to expand the movable range.

However, when it is determined whether or not the rotation position of the output gear is located within the dead zone of the position sensor based on position information obtained from the position sensor, the dead zone is not accurately determined in some cases. For example, noise brought about by a disturbance of a voltage output from the position sensor as position information may cause a misdetermination, indicating absence of the rotation position of the output gear within the dead zone of the position sensor even though the rotation position of the output gear is located within the dead zone of the position sensor. The above misdetermination causes a problem particularly when it is made at the power-on time after the power off when the rotation position of the output gear is located within the dead zone of the position sensor.

The present invention has been contrived in view of the conventional problem described above, and an object of the present invention is to avoid a misdetermination when it is determined whether or not the rotation position of an output gear is located within a dead zone of a position sensor in a rotating device.

### Solution to Problem

To solve the above problem, a rotating device described in an embodiment is a rotating device including: a control circuit configured to output drive pulses of a number corresponding to a drive target included in a drive command signal from outside; a drive circuit configured to output a drive voltage corresponding to the drive pulses; a stepping motor rotationally driven by the drive voltage output by the drive circuit; an output gear configured to rotate in conjunction with the rotational driving of the stepping motor; and a voltage output circuit configured to output, to the control circuit, a voltage corresponding to a rotation position of the output gear. The voltage output circuit includes a position detection circuit having a variable resistor with a first end being connected to a voltage source configured to apply a predetermined voltage and a second end being connected to a ground, and a voltage output line configured to output the voltage changing as a contact position in contact with the variable resistor moves in accordance with the rotation position of the output gear; and an adjustment resistor with a first end being connected to the voltage output line and a second end being connected to the ground and configured to adjust the voltage output from the voltage output line. The control circuit includes a dead zone determination processing unit configured to determine the contact position of the voltage output line being located within a dead zone formed between the variable resistor and the ground in the position detection circuit, when the voltage output from the voltage output circuit has a value less than or equal to a predetermined threshold value, and to execute processing corresponding to the dead zone when the contact position of the voltage output line is determined to be located within the dead zone. A resistance value of the adjustment resistor in the voltage output circuit is set to a value between a minimum value determined in a manner for a ratio of an adjustment voltage, output from the voltage output line in a case of the voltage output circuit having the adjustment resistor, to a reference voltage output from the voltage output line in a case of the voltage output circuit not having the adjustment resistor, to become greater than or equal to a predetermined value, and a maximum value determined in a manner for noise generated on the voltage output from the voltage output line with the contact position located within the dead zone to become less than or equal to a predetermined value.

### Advantageous Effects of Invention

The rotating device of the present invention can avoid a misdetermination when it is determined whether or not the rotation position of an output gear is located within a dead zone of a position sensor in the rotating device.

### BRIEF DESCRIPTION OF DRAWINGS

FIG. 1 is a schematic configuration diagram illustrating an example of a rotating device of a first embodiment.

FIG. 2 is a schematic configuration diagram illustrating an example of a relationship between a control device 10 and a stepping motor 20 in a rotating device 1 of the present embodiment.

FIG. 3 is a diagram illustrating a configuration of a conventional position sensor 80 alone.

FIG. 4 is a diagram explaining a dead zone of the position sensor 80.

FIG. 5 is a diagram illustrating a configuration of a voltage output circuit 75 of the present embodiment.

FIG. 6 is a graph showing a relationship between a resistance value Rx of an adjustment resistor 79 and a variation of an adjustment voltage Vx in a dead zone.

FIG. 7 is a diagram illustrating a configuration example of a function block achieved by a drive control unit 50 of a control circuit 30.

FIG. 8 is a flow diagram illustrating a flow of an initial setting operation at a power-on time in the control device 10 of the rotating device 1.

FIG. 9 is a flow diagram illustrating a flow of an operation with respect to the first drive command after the power on in the control device 10 of the rotating device 1.

FIG. 10 is a flow diagram for explaining operations of the control device 10 of the rotating device 1 of the first embodiment.

FIG. 11 is a diagram for explaining a rotation abnormality determination.

### DESCRIPTION OF EMBODIMENTS

### 1. Overview of Embodiment

First, an overview of a typical embodiment of the invention disclosed in the present application will be described. Note that, in the following description, reference signs in the drawings corresponding to the constituent elements of the invention are described in parentheses as an example.

[1] A rotating device (1) according to a typical embodiment of the present invention is the rotating device (1) including: a control circuit (30) configured to output drive pulses of a number corresponding to a drive target included in a drive command signal from outside; a drive circuit (40) configured to output a drive voltage corresponding to the drive pulses; a stepping motor (20) rotationally driven by the drive voltage output by the drive circuit (40); an output gear (74) configured to rotate in conjunction with the rotational driving of the stepping motor (20); and a voltage output circuit (75) configured to output, to the control circuit (30), a voltage (Vx) corresponding to a rotation position of the output gear (74). The voltage output circuit (75) includes a position detection circuit (80) having a variable resistor (77) with a first end being connected to a voltage source (E) configured to apply a predetermined voltage and a second end being connected to a ground, and a voltage output line (78) configured to output the voltage (Vx) changing as a contact position in contact with the variable resistor (77) in accordance with the rotation position of the output gear (74); and an adjustment resistor (79) with a first end being connected to the voltage output line (78) and a second end being connected to the ground and configured to adjust the voltage (Vx) output from the voltage output line (78). The control circuit (30) includes a dead zone determination processing unit (66) configured to determine the contact position of the voltage output line (78) being located within a dead zone formed between the variable resistor (77) and the ground in the position detection circuit (80), when the voltage (Vx) output from the voltage output circuit (75) has a value less than or equal to a predetermined threshold value, and to execute processing corresponding to the dead zone, when the contact position of the voltage output line (78) is determined to be located within the dead zone. A resistance value (Rx) of the adjustment resistor (79) in the voltage output circuit (75) is set to a value between a minimum value determined in a manner for a ratio of an adjustment voltage (Vx), being the voltage (Vx) output from the voltage output line (78) in a case of the voltage output circuit (75) having the adjustment resistor (79), to a reference voltage (Vo) output from the voltage output line (78) in a case of the voltage output circuit (75) not having the adjustment resistor (79), to become greater than or equal to a predetermined value, and a maximum value determined in a manner for noise generated on the voltage (Vx) output from the voltage output line (78) with the contact position located within the dead zone to become less than or equal to a predetermined value.

[2] In the rotating device described in the above aspect [1], when a resistance value of the variable resistor (77) is taken as Rv, a minimum value RxMin of a resistance value Rx of the adjustment resistor is determined by the following expression.

RxMin=r×Rv/(4×(1−r))

In the expression, r=adjustment voltage Vx/reference voltage Vo.

[3] In the rotating device described in the above aspect [2], r representing a ratio of the adjustment voltage Vx to the reference voltage Vo is 0.98 or more.

[4] In the rotating device described in any one of the above aspects [1] to [3], a maximum value RxMax of the resistance value Rx of the adjustment resistor (79) is 500 kΩ equivalent to a voltage of 250 mV or less of noise generated on the voltage (Vx) when a voltage value (Ve) of the voltage source (E) is 3.3 V.

[5] In the rotating device described in any one of the above aspects [1] to [4], when the dead zone determination processing unit (66) determines that the contact position of the voltage output line (78) being located within the dead zone at the power-on time, the dead zone determination processing unit (66) notifies occurrence of initial position abnormality to the outside.

[6] In the rotating device described in any one of the above aspects [1] to [5], the control circuit (30) further includes a rotation abnormality determination unit (51) configured to execute abnormality determination processing for determining whether or not rotation abnormality has occurred in the output gear (74) based on the voltage (Vx) output from the voltage output circuit (75), and a rotation abnormality determination restricting unit (51) configured to restrict the determination in the rotation abnormality determination unit (51) from being executed, when the contact position of the voltage output line (78) is located within the dead zone.

### 2. Specific Examples of Embodiment

Hereinafter, specific examples of the embodiments of the present invention will be described with reference to the accompanying drawings. Note that, in the following description, constituent elements common to each of the embodiments are denoted with the same reference signs and will not be described repeatedly.

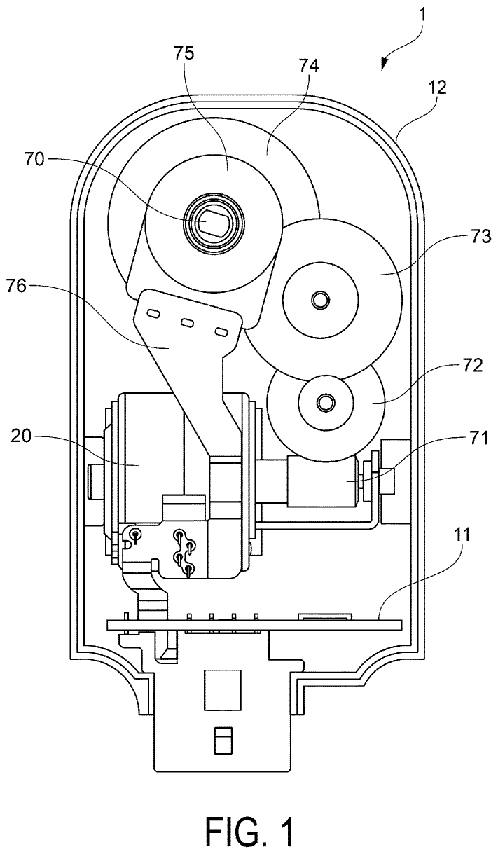

FIG. 1 is a schematic configuration diagram illustrating an example of the rotating device 1 of the present embodiment. As illustrated in FIG. 1, the rotating device 1 is configured to include a control board 11, the stepping motor 20, an actuator output shaft 70, a first gear 71, a second gear 72, a third gear 73, the output gear 74, the voltage output circuit 75, and a flexible printed circuit board (FPC) 76 in a housing 12.

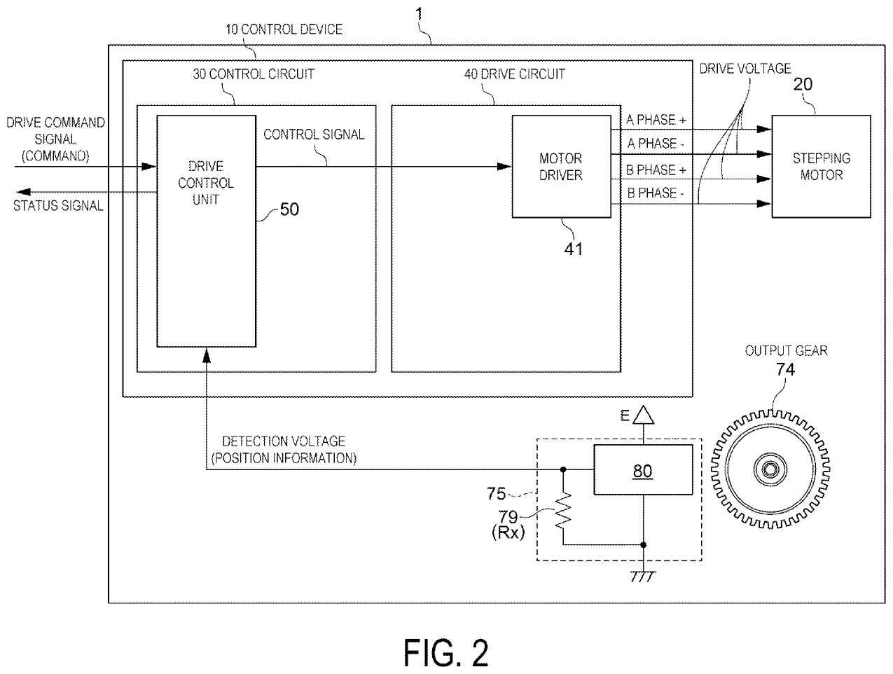

The control device 10 of the rotating device 1 (see FIG. 2) is mounted on the control board 11, and wiring is prepared in a manner to electrically connect the mounted control device 10 to the stepping motor 20 and the voltage output circuit 75 via the FPC 76. The control device 10 drives and rotates the output shaft of the stepping motor 20 by applying a drive voltage to the stepping motor 20. The control device 10 of the rotating device 1 of the present embodiment may receive, as position information, a voltage corresponding to the rotation position read by the voltage output circuit 75, but does not use the received position information for rotational driving (does not perform rotational driving by feedback based on the position information).

The first gear 71 is provided at the output shaft of the stepping motor 20. The second gear 72 and the third gear 73 rotate in conjunction with the rotational driving of the first gear 71 by the stepping motor 20. As the gears 71, 72, and 73 rotate, the output gear 74 is eventually rotated in conjunction with those gears.

The output gear 74 includes the actuator output shaft 70, and this actuator output shaft 70 is connected to an external drive object. The output gear 74 is provided with the voltage output circuit 75, and the rotation position of the output gear 74 may be read by measuring the voltage value changing in accordance with the rotation position.

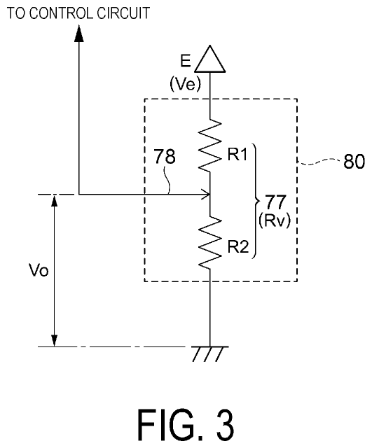

FIG. 2 is a schematic configuration diagram illustrating an example of a relationship between the control device 10 and the stepping motor 20 in the rotating device 1 of the present embodiment, and FIG. 3 is a diagram illustrating a configuration example of a function block achieved by the drive control unit 50 of the control circuit 30. As illustrated in FIG. 2, the control device 10 in the rotating device 1 is configured to include the control circuit 30 and the drive circuit 40.

A drive command signal (command) is input to the control circuit 30 from an upper level controller (an example of the outside) via a local interconnect network (LIN) or the like. The drive command signal is a signal including a drive target for driving the stepping motor 20 in a manner for a drive object connected to the actuator output shaft 70 to perform a desired operation. The drive target may use a rotation position of the actuator output shaft 70.

The control circuit 30 includes the drive control unit 50 configured to output drive pulses of the number corresponding to the drive target included in the drive command signal as a control signal to the drive circuit 40, and the drive circuit 40 includes a motor driver 41 configured to apply a drive voltage for driving the stepping motor 20.

A voltage (position information) output from the voltage output circuit 75 configured to read the rotation position of the output gear 74 is input to the drive control unit 50. The drive control unit 50 outputs a status signal indicating the drive state of the rotating device 1 to the upper level controller, as necessary.

First, the configuration and operations of a conventional position sensor 80 alone will be described as a prerequisite for describing the configuration of the voltage output circuit 75 of the present embodiment.

FIG. 3 is a diagram illustrating the configuration of the conventional position sensor 80 alone. The position sensor 80 (an example of the position detection circuit) may be configured as a so-called potentiometer, for example. As illustrated in FIG. 3, the position sensor 80 is configured of a variable resistor 77 with a first end being connected to a voltage source E configured to apply a predetermined voltage value Ve and a second end being connected to the ground, and a voltage output line 78. The position sensor 80 includes a variable resistance region provided with the variable resistor 77, and includes also a dead zone formed between the second end of the variable resistor 77 and the ground.

In the position sensor 80, the voltage output line 78 makes contact with any position in any of the variable resistance region based on a resistance value Rv of the variable resistor 77 and the dead zone present between the variable resistor 77 and the ground, and the contact position described above moves in accordance with the rotation position of the output gear 74. The variable resistor 77 is divided into an upper resistor R1 and a lower resistor R2 based on the contact position by the voltage output line 78. When the contact position of the voltage output line 78 with the variable resistor 77 moves, the ratio of the magnitude of the upper resistor R1 formed between the voltage source E and the voltage output line 78 and the magnitude of the lower resistor R2 formed between the voltage output line 78 and the ground changes, resulting in a change in an output detection voltage (reference voltage) Vo. In the dead zone formed between the second end of the variable resistor 77 and the ground, the detection voltage Vo does not change in accordance with the contact position because of the dead zone being in a high impedance state.

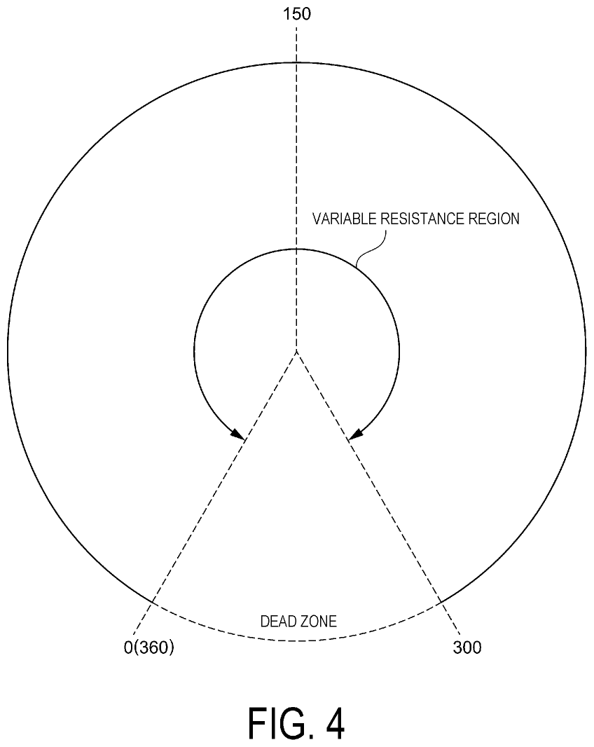

FIG. 4 is a diagram explaining the dead zone of the position sensor 80. In FIG. 4, numerical values from 0 to 360 indicate a rotation position of the output gear 74 (angles within one turn). As illustrated in FIG. 4, the rotation position of the output gear 74 corresponds to the variable resistance region and the dead zone of the position sensor 80. In the variable resistance region, as described above, because the detection voltage Vo output in accordance with the change in the ratio of the magnitude of the upper resistor R1 and magnitude of the lower resistor R2 changes, the position information (information indicating the rotation position of the output gear 74) can be acquired. On the other hand, in the dead zone, because the detection voltage Vo basically does not change, accurate position information cannot be acquired. Accordingly, in the rotating device 1, when processing using the position information from the position sensor 80 is carried out, processing different from that carried out in the variable resistance region needs to be executed in the dead zone.

The control circuit 30 connected to the voltage output line 78, as described below, includes a dead zone determination processing unit 66 configured to determine that the contact position of the voltage output line 78 is located within the dead zone of the position sensor 80 based on the voltage input from the voltage output line 78 (the detection voltage Vo output from the position sensor 80 in the configuration of the position sensor 80 alone), and execute the processing corresponding to the dead zone when the contact position of the voltage output line 78 is determined to be located within the dead zone of the position sensor 80. However, in the configuration of the position sensor 80 alone, since the voltage output line 78 is in an open state in the dead zone formed between the second end of the variable resistor 77 and the ground, the detection voltage Vo is not stable due to effect of noise. Because of this, in the configuration of the position sensor 80 alone, the detection voltage Vo in the dead zone changes from the true value effected by the noise, whereby a misjudgment may be made that the contact position of the voltage output line 78 (in other words, the rotation position of the output gear 74) is located within the variable resistance region regardless of the fact that the contact position of the voltage output line 78 is located within the dead zone of the position sensor 80.

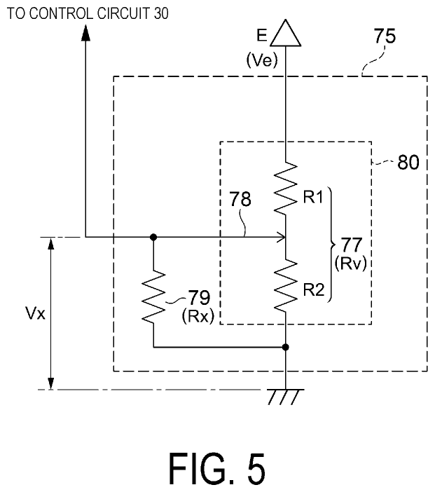

FIG. 5 is a diagram illustrating a configuration of the voltage output circuit 75 of the present embodiment. As illustrated in FIG. 5, the voltage output circuit 75 of the present embodiment further includes, in addition to the configuration of the position sensor 80 alone illustrated in FIG. 3, the adjustment resistor 79 with a first end being connected to the voltage output line 78 and a second end being grounded. Due to having the adjustment resistor 79, the voltage output line 78 is not brought into the open state. The voltage output line 78 is brought into a low-impedance state with the resistance value Rx of the adjustment resistor 79, so that the adjustment voltage (voltage) Vx is stabilized without being effected by the noise. Accordingly, when the contact position of the voltage output line 78 is located within the dead zone of the position sensor 80, the contact position of the voltage output line 78 can be correctly determined to be located within the variable resistance region of the position sensor 80 based on the adjustment voltage Vx output from the voltage output circuit 75.

Further, in the voltage output circuit 75 of the present embodiment, the resistance value Rx of the adjustment resistor 79 is set to a value between the minimum value RxMin and the maximum value RxMax. The reason for this is as follows: by providing the adjustment resistor 79, the voltage output line 78 is brought into the low-impedance state. This state can prevent misdetermination as to whether or not the contact position of the voltage output line 78 is located within the dead zone of the position sensor 80; however, when the above-described value (the resistance value Rx of the adjustment resistor 79) is unsuitable, the noise is not sufficiently suppressed, an error is generated on the contrary, or the like.

The minimum value RxMin of the resistance value Rx of the adjustment resistor 79 is determined based on the reference voltage Vo, as a detection voltage output from the voltage output line 78 at a position within the variable resistance region in the configuration of the position sensor 80 alone as illustrated in FIG. 3. In other words, the reference voltage Vo may be considered to be the detection voltage output from the voltage output line 78 at the position within the variable resistance region when the voltage output circuit 75 of the present embodiment does not include the adjustment resistor 79.

The minimum value RxMin of the resistance value Rx of the adjustment resistor 79 is a value determined in a manner for the ratio r of the adjustment voltage Vx, output from the voltage output line 78, to the reference voltage Vo (r=adjustment voltage Vx/reference voltage Vo) to be equal to or greater than a predetermined value. The minimum value RxMin of the resistance value Rx of the adjustment resistor 79 is determined using the resistance value Rv of the variable resistor 77 and the ratio r of the adjustment voltage Vx to the reference voltage Vo, specifically, determined by an expression indicated as RxMin=r×Rv/(4×(1−r)). The expression will be described below.

The variable resistor 77 is divided into the upper resistor R1 and the lower resistor R2, and thus is represented by Expression 1.

Rv=R1+R2 (Expression 1)

Subsequently, the reference voltage Vo and the adjustment voltage Vx are represented by Expression 2 and Expression 3, respectively, by using the voltage value Ve of the voltage source E.

Vo=R2/Rv×Ve (Expression 2)

Vx=R2×Rx/(R1×R2+R1×Rx+R2×Rx)×Ve (Expression 3)

The ratio r of the adjustment voltage Vx to the reference voltage Vo (r=adjustment voltage Vx/reference voltage Vo) is represented by Expression 4 using Expressions 1 to 3 described above.

r=Vx/Vo=Rx×Rv/(Rx×Rv+R1×R2) (Expression 4)

The upper resistor R1 and the lower resistor R2 are variable, and thus the ratio r of the adjustment voltage Vx to the reference voltage Vo takes a minimum value when R1 equals R2 in accordance with Expression 4. The ratio r of the adjustment voltage Vx to the reference voltage Vo at this time is represented by Expression 5.

R=4×Rx/(4×Rx+Rv) (Expression 5)

When this is solved for the resistance value Rx of the adjustment resistor 79, Expression 6 can be derived.

Rx=r×Rv/(4×(1−r)) (Expression 6)

In other words, when a difference between the reference voltage Vo and the adjustment voltage Vx is desired to be set to (1−r)×100%, the range of the resistance value Rx of the adjustment resistor 79 is represented by Expression 7.

Rx≥r×Rv/(4×(1−r)) (Expression 7)

In the voltage output circuit 75 of the present embodiment, the ratio r of the adjustment voltage Vx to the reference voltage Vo at the minimum value RxMin of the resistance value Rx of the adjustment resistor 79 is specifically 0.98 or greater.

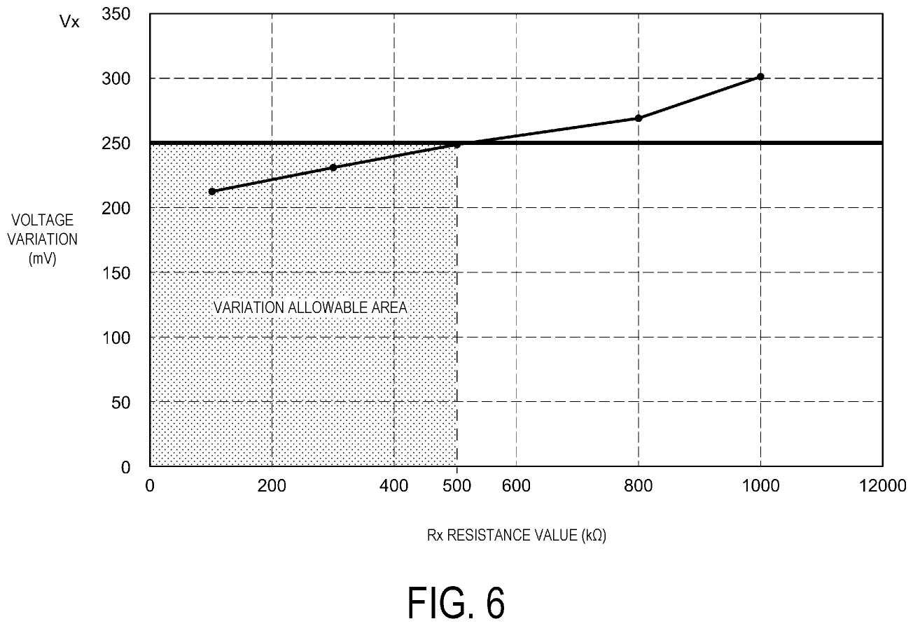

The maximum value RxMax of the resistance value Rx of the adjustment resistor 79 is determined in a manner for the noise generated on the adjustment voltage Vx output from the voltage output line 78 to be equal to or less than a predetermined value. The contact position is located within the dead zone of the position sensor 80. FIG. 6 is a graph showing a relationship between the resistance value Rx of the adjustment resistor 79 and a variation of the adjustment voltage Vx in the dead zone. As is apparent from FIG. 6, as the resistance value Rx of the adjustment resistor 79 increases, the variation of the adjustment voltage Vx in the dead zone increases. The range of the variation of the adjustment voltage Vx in this dead zone is considered as a noise band and is set as the dead zone, thereby making it possible to correctly determine the range of the variation to be the dead zone without being effected by the noise. On the other hand, when a range to be set as the dead zone (allowable noise range) is too large, the variable resistance region becomes narrow, and thus a predetermined limit value needs to be provided. The resistance value Rx of the adjustment resistor 79 having a voltage variation corresponding to the limit value may be determined to be the maximum value RxMax.

For example, in FIG. 6, noise up to 250 mV is considered allowable. In this case, as shown in FIG. 6, the resistance value Rx of the adjustment resistor 79 can be set to be 500 kΩ at the maximum. This resistance value Rx of the adjustment resistor 79 is the maximum value RxMax. As an example, the maximum value RxMax of the resistance value Rx of the adjustment resistor 79 is set to be 500 kΩ equivalent to a voltage of 250 mV or less of noise generated on the adjustment voltage Vx when the voltage value Ve of the voltage source E is 3.3 V.

Referring back to FIG. 2, in the rotating device 1 of the present embodiment, the adjustment voltage Vx detected by the voltage output circuit 75 including the adjustment resistor 79 set as described above is input as position information to the drive control unit 50 of the control circuit 30.

The drive control unit 50 of the control circuit 30 includes the dead zone determination processing unit 66 configured to determine the contact position of the voltage output line 78 to be located within the dead zone of the position sensor 80 when the voltage (adjustment voltage Vx) output from the voltage output circuit 75 is equal to or less than a predetermined threshold value, and execute the processing corresponding to the dead zone when the contact position of the voltage output line 78 is determined to be located within the dead zone of the position sensor 80. In the following example, the drive control unit 50 of the control circuit 30 configured to execute the processing for determining rotation abnormality of the rotating device 1 with using the voltage (adjustment voltage Vx; position information) from the voltage output circuit 75 described above is cited as an example, and the configuration of the drive control unit 50 will be described.

Specifically, the dead zone determination processing unit 66 in the drive control unit 50 determines whether or not the voltage (adjustment voltage Vx) indicates the rotation position of the output gear 74 to be located within the dead zone of the position sensor 80 (indicates an abnormal value) at the power-on time after the power off, and determines occurrence of initial position abnormality when the adjustment voltage Vx indicates the rotation position of the output gear 74 to be located within the dead zone of the position sensor 80 and notifies the occurrence of the initial position abnormality to the upper level controller.

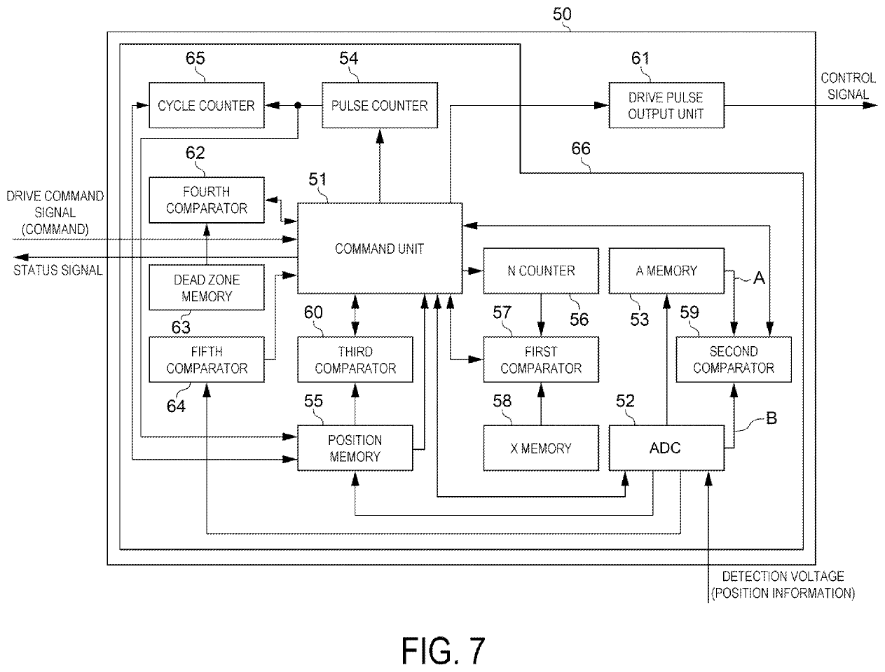

FIG. 7 is a diagram illustrating a configuration example of a function block achieved by the drive control unit 50 of the control circuit 30.

For example, the drive control unit 50 includes hardware elements including a processor such as a CPU, various types of memories such as a ROM, a RAM and the like, a timer (counter), an A/D conversion circuit, an input-output I/F circuit and a clock generation circuit, and is constituted by a program processing unit, for example, a micro controller (MCU). In this program processing unit, each constituent element is connected to each other via a bus, or a dedicated line.

The drive control unit 50 achieves a configuration of each of the function units, as illustrated in FIG. 7, by the processor performing various arithmetic operations in accordance with programs stored in a storage unit (not illustrated) such as a memory, and the processor performing control of peripheral circuits such as an A/D conversion circuit, an input-output I/F circuit and the like. In other words, as illustrated in FIG. 7, the drive control unit 50 includes, as function units, a command unit (an example of the rotation abnormality determination unit, the rotation abnormality determination restricting unit, and the dead zone determination processing unit) 51, an AD converter (ADC) 52, an A memory 53, a pulse counter 54, a position memory 55, an N counter 56, a first comparator 57, an X memory 58, a second comparator 59, a third comparator 60, a drive pulse output unit 61, a fourth comparator 62, a dead zone memory 63, a fifth comparator 64, and a cycle counter 65. Each of the function units in the drive control unit 50 may execute various kinds of processing based on commands given by the command unit 51.

In the drive control unit 50, the command unit 51, the AD converter 52, the A memory 53, the pulse counter 54, the position memory 55, the N counter 56, the first comparator 57, the X memory 58, the second comparator 59, the third comparator 60, the fourth comparator 62, the dead zone memory 63, the fifth comparator 64, and the cycle counter 65 collaborate with one another to function as the dead zone determination processing unit 66.

When the command unit 51 receives a drive command signal from the upper level controller (not illustrated; an example of the outside), the command unit 51 outputs drive pulses of the number corresponding to the drive target included in the drive command signal to the drive pulse output unit 61, and outputs a count command to the pulse counter 54 and the N counter 56. The command unit 51 is capable of calculating the number of drive pulses needed to reach the drive target included in the drive command signal, as a target count value.

The command unit 51 may output, to the AD converter 52, a command to acquire position information A (reference position information, first position information) at a predetermined timing, such as the start of the output of the drive pulses, and store the acquired position information A in the A memory 53. The command unit 51 may send comparison commands to the first comparator 57, the second comparator 59, the third comparator 60, the fourth comparator 62, and the fifth comparator 64 at a predetermined timing. The command unit 51 performs various kinds of judgment control based on the comparison results received from the comparators 57, 59, 60, 62, and 64.

The AD converter 52 receives the command from the command unit 51 to acquire the voltage (adjustment voltage Vx) corresponding to the rotation position input from the voltage output circuit 75, and stores an AD-converted value (hereinafter, also referred to as an ADC value) as the first position information in the A memory 53. Thereafter, the AD converter 52 receives a command from the command unit 51 at the timing of rotation abnormality determination, and delivers an AD-converted value (ADC value) obtained by performing AD conversion on the voltage (adjustment voltage Vx) corresponding to the rotation position input from the voltage output circuit 75 to the second comparator 59 as second position information. The second position information acquired at the timing of rotation abnormality determination is delivered to the second comparator 59, and is overwritten on the information stored as the first position information in the A memory 53, thereby making it possible to update the reference position at the timing of rotation abnormality determination.

The drive pulse output unit 61 receives a command from the command unit 51 to output the drive pulses to the motor driver 41 of the drive circuit 40.

The pulse counter 54 receives a command from the command unit 51 to increment the counter, and delivers the incremented pulse count value to the position memory 55 and the cycle counter 65. The cycle counter 65, when having received the pulse count value from the pulse counter 54, refers to the current rotation position of the output gear 74 (a position count value: a value corresponding to an angle from 0 to 360 degrees) stored in the position memory 55, adds the pulse count value received from the pulse counter 54 to the position count value so as to increment a cycle count value by the number of times the output gear 74 passes a boundary (reference position) in a forward direction within one turn of the position sensor 80, and delivers the incremented cycle count to the position memory 55. The position memory 55 adds the acquired pulse count value and cycle count value to the position (the position count value and cycle count value) corresponding to the currently stored rotation position of the output gear 74 so as to newly store (update the current information by) the calculation results as the information of the rotation position (the position count value and cycle count value), and notifies the command unit 51 of having stored the new rotation position information. That is, the current position (position) in the position memory 55 is updated using the pulse count value and the cycle count value.

The command unit 51 may transmit, as necessary, the position stored in the position memory 55 as a status signal to the upper level controller. In the rotating device 1 of the present embodiment, the current position (position) stored in the position memory 55 is managed by the position count value and the cycle count value. The position within a conventional 360-degree rotation range (that is, within one turn) may be managed with a position count value P, and in a region beyond the 360-degree rotation range (that is, in a region beyond one turn), the position may be managed using a cycle count value n as well. When a wiper of the position sensor 80 passes the reference position (for example, 0 degrees) clockwise (an example of the forward direction), the cycle count value n is incremented by one, and when the wiper of the position sensor 80 passes the reference position (for example, 0 degrees) counterclockwise (an example of a reverse direction), the cycle count value n is decreased by one. The position stored in the position memory 55 may be represented as follows: when three turns are defined as a position of 1000, for example, the current rotation position is represented by the sum of a position of n×(1000÷3) corresponding to the cycle count value n and a position of (P÷360)×(1000÷3) corresponding to the position count value P. The command unit 51 may report the current position using the position count value P and the cycle count value n to the upper level controller. This makes it possible to use the rotating device 1 of the present embodiment in a mechanism requiring a rotation of 360 degrees or more, such as a rack mechanism, a link mechanism or the like. Note that the reference position is not limited to 0 degrees, and may be set to be at any angular position.

The N counter 56 receives a command from the command unit 51 to increment the counter, and holds the incremented count value (the N count value). The first comparator 57 receives the command from the command unit 51 to compare a predetermined value (also referred to as an X value) held in the X memory 58 with the N count value held in the N counter 56, and returns the comparison result to the command unit 51.

The command unit 51 judges whether or not the current timing is a timing for determining rotation abnormality based on the comparison result received from the first comparator 57. When it is a timing for determining rotation abnormality, the command unit 51 commands the second comparator 59 to execute comparison processing for determining rotation abnormality.

The X value held in the X memory 58 serves as a reference of the timing for determining rotation abnormality of the rotating device 1. The X value may be set based on the performance of the position sensor 80, and the value of the X value is not limited to any specific value. When the performance of the position sensor 80 is low, the X value is made to be large, and when the performance of the position sensor 80 is high, the X value is made to be low, whereby making it possible to precisely determine rotation abnormality with appropriate resolution in accordance with the performance of the position sensor 80.

The second comparator 59 receives the command from the command unit 51 to compare the position information A (first position information) stored in the A memory 53 with position information B (second position information) acquired via the AD converter 52, and returns the comparison result to the command unit 51.

The command unit 51 judges whether or not rotation abnormality has occurred, based on the comparison result received from the second comparator 59. When no rotation abnormality has occurred, the command unit 51 commands the third comparator 60 to execute processing for determining a stop condition.

The third comparator 60 receives the command from the command unit 51 to compare the position (the position count value and cycle count value) held in the position memory 55 with the target count value taken as the drive target, and returns the comparison result to the command unit 51.

The command unit 51 may judge, based on the comparison result received from the third comparator 60, the drive pulse needs to be emitted when there is a difference between the position and the target count value, and may judge the stop condition to be satisfied when the position matches the target count value.

The fourth comparator 62 receives the command from the command unit 51 at the timing of the rotation abnormality determination to compare the position count value indicating the rotation position of the output gear 74 driven by the drive pulse with the rotation position corresponding to the dead zone of the position sensor 80 stored in the dead zone memory 63, and delivers the comparison result to the command unit 51. The position count value may be acquired from the position memory 55 and delivered to the fourth comparator 62 when the command unit 51 gives the command to the fourth comparator 62.

The command unit 51 judges whether or not the rotation position of the output gear 74 rotated by the stepping motor 20 is located within the dead zone of the position sensor 80, based on the comparison result received from the fourth comparator 62. When the rotation position of the output gear 74 is judged to be located within the dead zone of the position sensor 80, the command unit 51 functions as the rotation abnormality determination restricting unit and performs control in a manner not to execute the rotation abnormality determination even at the timing for determining rotation abnormality. That is, when the rotation position of the output gear 74 rotated by the stepping motor 20 is located within the dead zone of the position sensor 80 being unable to read the rotation position in this zone, the command unit 51 may function as the rotation abnormality determination restricting unit so as to restrict the rotation abnormality determination being executed. The processing for determining whether or not the rotation position of the output gear 74 is located within the dead zone of the position sensor 80 based on the comparison result received from the fourth comparator 62 does not utilize the voltage (adjustment voltage Vx; position information) from the voltage output circuit 75.

The reason for restricting the rotation abnormality determination processing in the dead zone of the voltage output circuit 75 will be described below using FIG. 4. The first position information and the second position information compared with each other by the second comparator 59 at the time of the rotation abnormality determination in the rotating device 1 of the present embodiment are values obtained by AD-converting the voltages corresponding to the rotation positions input from the voltage output circuit 75 having the position sensor 80. In the position sensor 80, as illustrated in FIG. 4, there is a region referred to as the dead zone. In this region, the voltage cannot be measured in part of the whole rotation positions (a region where the rotation position is between “300” and “360 (=0)”). The position sensor 80 is unable to read the rotation position in the dead zone, and thus the dead zone is not considered as a rotatable range in regular control. This is because even if it is attempted to perform rotation abnormality determination when the rotation position of the output gear 74 is located within the dead zone of the position sensor 80, the rotation abnormality determination cannot be executed accurately.

In the rotating device 1 of the present embodiment, information of the dead zone of the position sensor 80 (information indicating the location of the dead zone in the regions of rotation positions) is stored in the dead zone memory 63, and all the rotation positions are made to be a rotatable range while referring to the dead zone memory 63 and restricting not to perform the rotation abnormality determination when the rotation position of the output gear 74 by the drive command signal is located within the dead zone of the position sensor 80. In FIG. 4, in the dead zone, the rotation position is between “300” and “360 (=0)”, and thus a region from the rotation position exceeding “0” to the rotation position “300” is a position detectable region. The position detectable region corresponds to the variable resistance region of the position sensor 80.

At the power-on time, the fifth comparator 64 receives the command from the command unit 51 to compare the position information (ADC value) acquired from the AD converter 52 with a predetermined value defined as an abnormal value, and delivers the comparison result to the command unit 51. The abnormal value is a value acquired from the AD converter 52 when the position sensor 80 has failed to obtain a value, and is a value indicating the rotation position of the output gear 74 to be located within the dead zone of the position sensor 80. For example, it is a value such as the position information being “0” acquired from the AD converter 52, while the voltage value of the voltage (adjustment voltage Vx) determined to be the dead zone is set to a predetermined threshold value in consideration of effects of noise. For example, when the voltage value Ve of the voltage source E of the position sensor 80 is 3.3 V, 250 mV is set as the predetermined threshold value so as to allow noise to be generated with a voltage up to 250 mV or less on the adjustment voltage Vx.

In the rotating device 1 of the present embodiment, the voltage output circuit 75 including the position sensor 80 is provided with the adjustment resistor 79 having the resistance value Rx in an appropriate range on the voltage output line 78, whereby the voltage (adjustment voltage Vx) is stable, and the dead zone may be accurately determined in the fifth comparator 64.

The command unit 51 judges whether or not the position information acquired from the AD converter 52 indicates an abnormal value, based on the comparison result received from the fifth comparator 64. When the position information acquired from the AD converter 52 at the power-on time indicates the abnormal value, the command unit 51 may notify the upper level controller of initial position abnormality representing the position information acquired from the AD converter 52 indicating the rotation position of the output gear 74 being located within the dead zone of the position sensor 80. In other words, the command unit 51 functions as the dead zone determination processing unit, and when the position information acquired from the AD converter 52 at the power-on time indicates the rotation position of the output gear 74 being located within the dead zone of the position sensor 80, the command unit 51 may determine occurrence of the initial position abnormality, and notify the upper level controller (an example of the outside) of the initial position abnormality.

Operations of the control device 10 at the power-on time in the rotating device 1 of the first embodiment described above will be described.

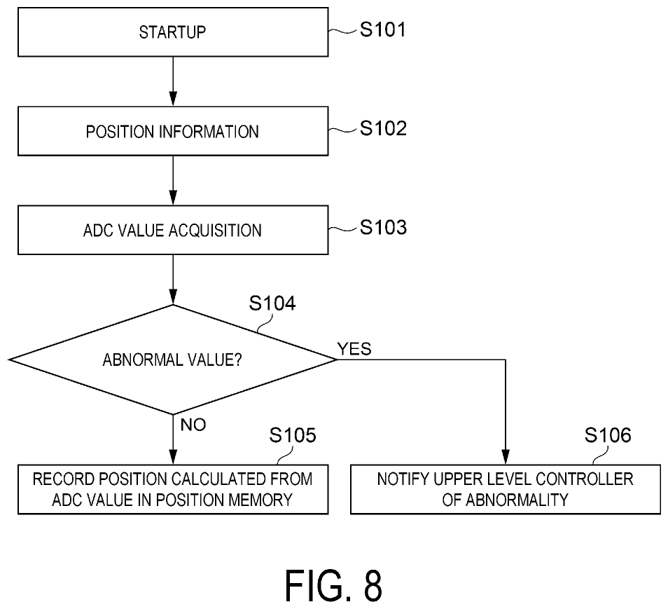

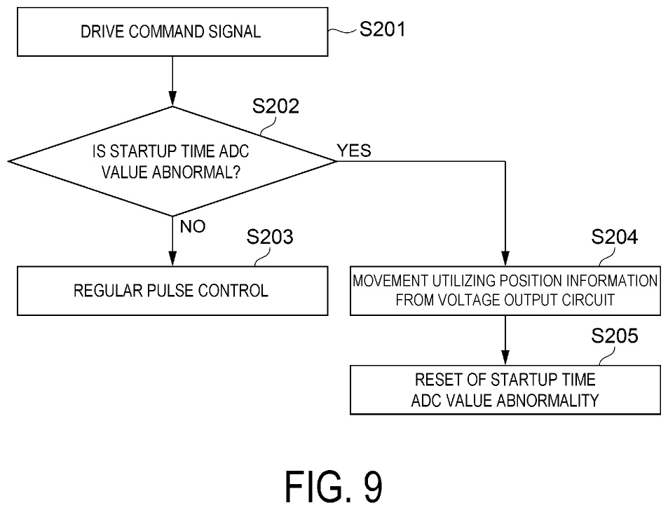

FIG. 8 is a flow diagram illustrating a flow of an initial setting operation at the power-on time in the control device 10 of the rotating device 1, and FIG. 9 is a flow diagram illustrating a flow of an operation with respect to a first drive command after the power on in the control device 10 of the rotating device 1.

First, as illustrated in FIG. 8, when the control device 10 of the rotating device 1 is started up (step S101), the AD converter 52 acquires a voltage (adjustment voltage Vx; position information) corresponding to a rotation position input from the voltage output circuit 75 including the position sensor 80 (step S102), and delivers an AD-converted value (a startup time ADC value) as initial position information to the fifth comparator 64 (step S103). The fifth comparator 64 compares the initial position information (startup time ADC value) with an abnormal value (a voltage threshold indicating the rotation position of the output gear 74 being located within the dead zone of the position sensor 80), the comparison result is received by the command unit 51, and the command unit 51 functions as the dead zone determination processing unit to determine whether or not the comparison result indicates an abnormal value (step S104).

When the initial position information does not indicate the abnormal value (step S104: NO), the command unit 51 records a position calculated from the initial position information (startup time ADC value) in the position memory 55 (step S105). On the other hand, when the initial position information indicates an abnormal value (step S104: YES), the command unit 51 notifies the outside, such as the upper level controller, of the position information acquired at the power-on time indicating the rotation position of the output gear 74 being located within the dead zone of the position sensor 80 (initial position abnormality has occurred) (step S106).

As described above, when the position information acquired from the AD converter 52 at the power-on time indicates the rotation position of the output gear 74 being located within the dead zone of the position sensor 80, the command unit 51 may notify the upper level controller of the above situation, whereby the upper level controller may understand the command unit 51 having failed to acquire the position information correctly from the AD converter 52 at the power-on time.

Subsequently, as illustrated in FIG. 9, when the command unit 51 receives the first drive command signal after the power on (step S201), the command unit 51 judges whether or not the startup time ADC value output from the AD converter 52 is abnormal (initial position abnormality) (step S202). When the startup time ADC value output from the AD converter 52 is not abnormal (step S202: NO), the command unit 51 performs regular drive control based on a drive target included in the drive command signal (step S203). In the regular drive control, in order to move to the drive target, the drive control is performed by outputting drive pulses of the required number of pulses.

When the startup time ADC value output from the AD converter 52 is abnormal (step S202: YES), the command unit 51 utilizes the position information (adjustment voltage Vx) from the voltage output circuit 75 including the position sensor 80 to move the rotation position of the stepping motor 20 (step S204) unlike the regular drive control. Specifically, the processing in step S204 moves the rotation position of the stepping motor 20 by the drive pulse output unit 61 outputting the drive pulses until the ADC value output from the AD converter 52 is made to be not an abnormal value. At this time, the stepping motor 20 rotates until the rotation position of the output gear 74 comes to be in the position detectable region of the position sensor 80. That is, after the command unit 51 determined occurrence of the initial position abnormality, when the command unit 51 has received the first drive command signal after the power on, the drive pulse output unit 61 outputs drive pulses needed until the AD converter 52 can acquire position information based on the rotation position read by the position sensor 80, instead of outputting drive pulses of the number corresponding to the drive target included in the drive command signal.

When the rotation position of the output gear 74 has rotated to be in the position detectable region of the position sensor 80, a startup time ADC value abnormality is reset (step S205). At this time, the command unit 51 may record, in the position memory 55, a position calculated from the ADC value output from the AD converter 52 after the movement to the position detectable region of the position sensor 80, as the current rotation position of the output gear 74. After the recording in the position memory 55, regular drive operation may be performed.

As described above, even when the position information output from the AD converter 52 and acquired at the power-on time indicates the rotation position of the output gear 74 being located within the dead zone of the position sensor 80, the command unit 51, in accordance with the drive command signal, may move the rotation position of the output gear 74 to the position detectable region of the position sensor 80 and acquire the position information, and then may perform the regular drive operation. That is, even when the rotation position of the output gear 74 is located within the dead zone of the position sensor 80 at the power-on time due to having been driven, before the power on, based on the drive target corresponding to the dead zone of the position sensor 80, the drive operation can be started without any trouble, and thus making it possible to include even the rotation position corresponding to the dead zone of the position sensor 80 in the rotatable range.

Next, operations of the control device 10 in the rotating device 1 of the first embodiment discussed above will be described.

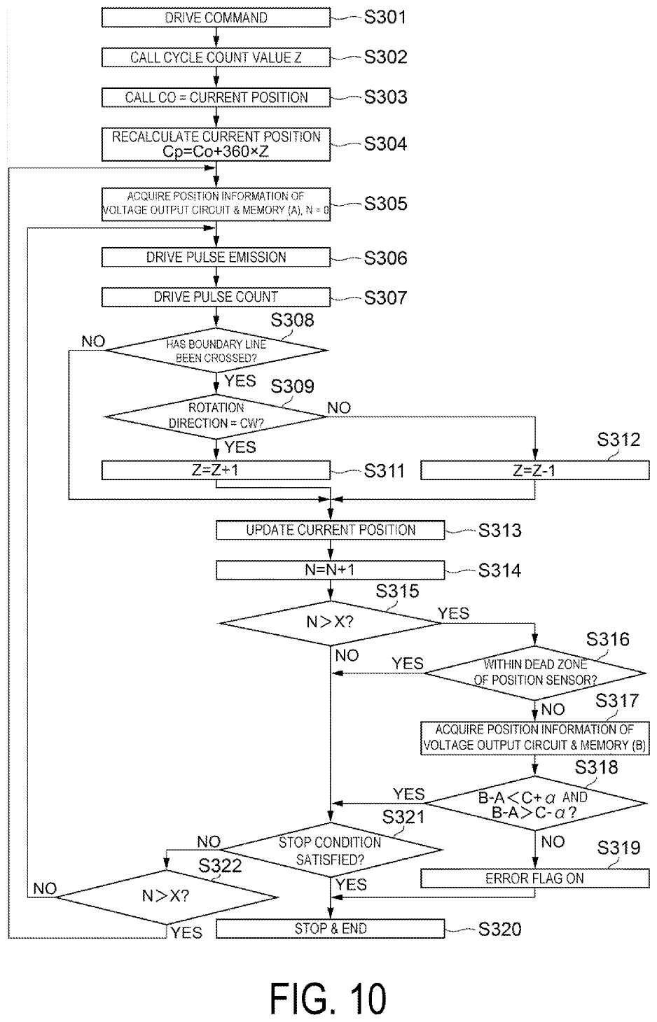

FIG. 10 is a flow diagram for explaining the operations of the control device 10 in the rotating device 1 of the first embodiment. In the control device 10 of the rotating device 1 of the present embodiment, the command unit 51 receives a drive command signal (command) from the upper level controller (step S301) so as to start the operations in FIG. 10.

A control method for the rotating device 1 of the present embodiment includes: a drive pulse output step of repeatedly outputting a drive pulse for the number of times corresponding to the drive target with respect to the drive circuit 40 configured to apply a drive voltage to the stepping motor 20 for rotating the output gear 74 of the rotating device 1; a position information acquisition step of acquiring position information from the voltage output circuit 75 including the position sensor 80 for reading a rotation position of the output gear 74 at a predetermined repeat timing of the drive pulse output step; a dead zone determination step of determining as to whether or not the rotation position of the output gear 74 rotated by the stepping motor 20 is located within a dead zone of the position sensor 80, being unable to read the rotation position; and a rotation abnormality determination step of determining as to whether or not rotation abnormality has occurred in the rotating device 1 based on the position information acquired in the position information acquisition step only when the rotation position of the output gear 74 is determined not to be located within the dead zone of the position sensor 80 in the dead zone determination step.

When the command unit 51 receives a drive command signal from the upper level controller, the command unit 51 first performs various setting operations for appropriately performing the rotation abnormality determination, prior to performing drive pulse emission processing. Specifically, the command unit 51 calls a cycle count value Z from the position memory 55 (step S302), calls a position count value Co (step S303), and recalculates the current position of the output gear 74 (step S304). The recalculation of a current position Cp may be calculated by an expression of Cp=position count value Co+360×cycle count value Z.

Thereafter, the command unit 51 commands the AD converter 52 to acquire the current position information read by the voltage output circuit 75 including the position sensor 80. The AD converter 52 acquires position information (an example of the first position information) A read by the voltage output circuit 75 including the position sensor 80 as a reference position, and stores the acquired position information A in the A memory 53 (step S305). At the timing of step S305, the N counter 56 receives a reset command from the command unit 51 and resets the value of the N counter to be zero.

Subsequent to step S305, the drive pulse output unit 61 receives a drive pulse emission command from the command unit 51 and emits a drive pulse to the motor driver 41 of the drive circuit 40 (step S306; the drive pulse output step). As a result, the drive voltage is applied to the stepping motor 20 by the motor driver 41, thereby the motor being driven and controlled.

Subsequent to step S306, the pulse counter 54 receives a drive pulse count command from the command unit 51 to increment the counter (step S307), and delivers the incremented pulse count value to the position memory 55 and the cycle counter 65.

The cycle counter 65 refers to the current rotation position (position count value) of the output gear 74 stored in the position memory 55, and adds the pulse count value received from the pulse counter 54 to the position count value so as to determine whether or not the wiper of the position sensor 80 has crossed a boundary line (reference position) of one turn (step S308); when the wiper of the position sensor 80 has crossed the boundary line (step S308: YES), it is further determined whether or not the rotation direction of the position sensor 80 is a forward direction (CW) (step S309). When the rotation direction of the position sensor 80 is determined to be the forward direction (step S309: YES), the cycle counter 65 adds “1” to the cycle count value Z (step S311); and when the rotation direction of the position sensor 80 is determined to be a reverse direction (step S309: NO), the cycle counter 65 subtracts “1” from the cycle count value Z (step S312); then, the cycle count value is delivered to the position memory 55.

When the position memory 55 has received the incremented pulse count value and the cycle count value, the position memory 55 updates the current position (position count value) of the output gear 74 based on the position recalculated in step S304 and the received pulse count value and cycle count value (step S313). This causes the position count value to be updated until the drive target (target count value) is reached.

Subsequent to step S313, the N counter 56 receives an N counter count command from the command unit 51 and increments the N counter value (step S314; the position information acquisition step). As a result, the N counter value reflects the number of the drive pulse emissions at each predetermined interval of the rotation abnormality determination.

Subsequent to step S314, the first comparator 57 receives the comparison command from the command unit 51 and compares the N counter value of the N counter 56 with the X value held in the X memory 58 (determines whether or not the N counter value is greater than the X value) (step S315), and delivers the comparison result to the command unit 51. Thus, since the X value as a reference of the timing of determining rotation abnormality of the rotating device 1 and the N counter value reflecting the number of the drive pulse emissions are compared with each other, a timing of the rotation abnormality determination to be performed at the predetermined rotation abnormality determination interval can be judged.

When the command unit 51 has received the comparison result of the N counter value being greater than the X value (step S315: YES), the command unit 51 judges that the comparison result indicates the predetermined rotation abnormality determination interval, and further judges whether or not the rotation position of the output gear 74 is located within the dead zone of the position sensor 80 based on the comparison result received from the fourth comparator 62 (step S316; the dead zone determination step); when the rotation position of the output gear 74 is judged not to be located within the dead zone of the position sensor 80 (step S316: NO), the rotation abnormality determination processing is executed. Specifically, the command unit 51 requires the AD converter 52 to acquire the current position information and gives a comparison command to the second comparator 59. When the second comparator 59 has received the comparison command from the command unit 51, the second comparator 59 acquires the position information A stored in the A memory 53 and the current position information (an example of the second position information) B acquired by the AD converter 52 (step S317). Subsequent to step S317, the second comparator 59 calculates a difference D between the position information A and the position information B (=B−A or =A−B), and compares the calculated difference D with a value obtained by adjusting a previously-held ideal difference C with an allowable value α ((C−α) and (C+α)) (step S318; the rotation abnormality determination step), and delivers the comparison result to the command unit 51. The allowable value α may be set to be any value. In addition, absolute values of −α and +α may be set to have different values. The ideal difference C is a value determined by multiplying the number of drive pulses output between the time when the previous rotation abnormality determination processing is executed and the time when the current rotation abnormality determination processing is executed, by the amount of change of the rotation position per unit drive pulse.

When the command unit 51 receives the comparison result that the calculated difference D does not fall within a range of the value obtained by adjusting the ideal difference C with the allowable value α (a relation of (C−α)<D<(C+α) is not satisfied) (step S318: NO), the command unit 51 determines that rotation abnormality has occurred in the rotating device 1 and sets an error flag to be ON (step S319), and commands the drive pulse output unit 61 to stop outputting the drive pulse. As a result, the driving of the stepping motor 20 is stopped (step S320). The processing in step S319 for setting the error flag to be ON may be omitted.

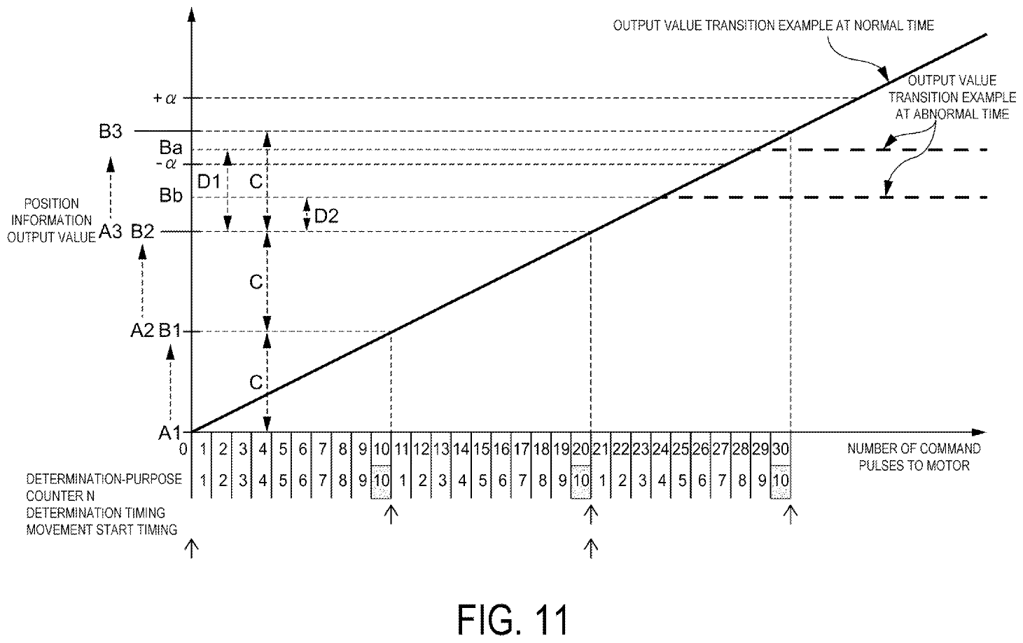

The rotation abnormality determination processing will be further shown below using FIG. 11. FIG. 11 is a diagram for explaining the rotation abnormality determination. FIG. 11 shows and exemplifies a case when the number of command pulses for one drive action of the stepping motor 20 output in accordance with the drive command signal is 20 pulses, and when the predetermined rotation abnormality determination interval of the pulses is 10 pulses (that is, the X value is 9), and the allowable value is α. Note that this example represents merely an example of numerical values, and is not limited to the above-described numerical values.

In FIG. 11, the number of command pulses with respect to the stepping motor 20 is indicated on the horizontal axis, and the position information output value (the value of the position information output from the voltage output circuit 75) is shown on the vertical axis. A determination-purpose counter N (N counter value), a rotation abnormality determination timing, and a movement start timing are indicated along the horizontal axis. In this example, it is understood that the N counter value is updated every 10 counts and the determination timing is set every 10 pulses (counts). Furthermore, the drawing indicates pieces of position information A1, A2, and A3 being stored as the first position information in the A memory 53 as reference positions. Pieces of position information B1, B2, and B3 indicate ideal second position information corresponding to the position information A1, A2, and A3 respectively.

In the control device 10 of the rotating device 1 of the present embodiment, as shown by a graph line of an output value transition example at a normal time in FIG. 11, the output value (value of position information) of the voltage output circuit 75 increases as the number of drive pulses increases at the normal time. However, when rotation abnormality occurs, a value off this graph line is shown.

For example, at the determination timing of the 30th step, a case of “Ba” being acquired as the current position information B and a case of “Bb” being acquired as the current position information B are shown.

In this example, at the previous determination timing of the 30th step determination timing, the position information A3 is stored as the first position information in the A memory 53 as the reference position. Accordingly, when “Ba” is acquired as the current position information (an example of the second position information) B, a difference D1 takes a value of Ba−A3. This difference D1 falls within a range of a value obtained by adjusting the ideal difference C with the allowable value α. Therefore, rotation abnormality is not determined in this case.

On the other hand, when “Bb” is acquired as the current position information (an example of the second position information) B, a difference D2 takes a value of Bb−A3. This difference D2 does not fall within the range of the value obtained by adjusting the ideal difference C with the allowable value α. Accordingly, in this case, “B3”, as a position corresponding to the number of output pulses, is considered not to be reached, and then rotation abnormality is determined. In other words, the command unit 51 functions as the rotation abnormality determination unit, and determines occurrence of rotation abnormality in the rotating device 1 when the difference D between the first position information acquired at the previous time by the AD converter 52 and the second position information acquired at this time by the AD converter 52 differs from the ideal difference C by a value greater than or equal to the allowable value α.

On the other hand, in step S315 in FIG. 10, when the command unit 51 has received the comparison result indicating the N counter value being not greater than the X value (step S315: NO), the command unit 51 may judge it is not a timing of performing rotation abnormality determination. Similarly, when the command unit 51 judges the rotation position of the output gear 74 being located within the dead zone of the position sensor 80 based on the comparison result received from the fourth comparator 62 (step S316: YES), the command unit 51 may also judge it is not the timing of performing rotation abnormality determination. In addition, when the command unit 51 has received the comparison result indicating the calculated difference D falling within a range of the value obtained by adjusting the ideal difference C with the allowable value α (the relation of (C−α)<D<(C+α) is satisfied) (step S318: YES), the command unit 51 may judge, as a result of the rotation abnormality determination, it is judged no abnormality is determined. In these cases (step S315: NO, step S316: YES, and step S318: YES), the command unit 51 gives a comparison command to the third comparator 60 for determining the stop condition. When the third comparator 60 has received the comparison command, the third comparator 60 compares the target count value and the position count value to determine whether the stop condition is satisfied (step S321), and delivers the comparison result to the command unit 51.

When the command unit 51 has received the comparison result indicating the stop condition being satisfied because the position count value has reached the target count value (step S321: YES), the command unit 51 ends the emission of the drive pulse (step S320).

When the command unit 51 has received the comparison result indicating the stop condition not being satisfied because the position count value has not reached the target count value yet (step S321: NO), the command unit 51 determines whether or not it has been the rotation abnormality determination timing based on whether or not the comparison result received in step S315 indicates the N counter value being greater than the X value (step S322). When the command unit 51 determines, as a result of the determination in step S322, it is the rotation abnormality determination timing (step S322: YES), the command unit 51 returns to the processing in step S305. When the command unit 51 determines, as a result of the determination in step S322, it is not the rotation abnormality determination timing (step S322: NO), the command unit 51 returns to the processing in step S306.

According to the drive control unit 50 having the above-described configuration, control of the rotation position of the stepping motor is performed conventionally by open control based on the drive command signal. That is, position information by a position sensor is not used as position information in the regular motor drive, so that high position accuracy and high resolution of the conventional stepping motor are not degraded. On the other hand, it is sufficient for the position information to be such a level of information making it possible to determine whether or not the output gear has moved physically. This makes it possible to use an inexpensive position sensor with rough accuracy without requiring a highly accurate position detection tool such as a position sensor used for regular position detection, and thus making it possible to achieve a scheme for obtaining position information at low cost.

In addition, despite the presence of a dead zone not enabling acquiring of position information within a range of one turn of the position sensor, even a rotation position beyond the whole rotation positions and one turn (360 degrees) of the position sensor may be included in a movable range; accordingly, the movable range can be made greater than the conventional rotating devices.

According to the rotating device of the present embodiment described above, because of using a stepping motor, the accuracy of rotation position control is high despite the simple configuration. On the other hand, even when processing using position information from the position sensor with a dead zone being present is executed, the dead zone may also be included in the rotation position by executing different pieces of processing depending on whether the processing is executed for the dead zone or not, so that the movable range is not narrowed. Furthermore, since the adjustment resistor having a resistance value set within a predetermined range is provided on the voltage output line of the position sensor, the dead zone can correctly be determined based on the position information from the position sensor with the dead zone being present.

### Modification of Embodiment

In the above-described embodiment, the configuration of the rotating device is not limited to the configuration illustrated in FIGS. 1 and 2, and the configuration of the drive control unit is not limited to the configuration illustrated in FIG. 7.

In the above-described embodiments, the processing flows illustrated in FIGS. 8, 9, and 10 are specific examples, and the processing flows are not limited to those examples.

### REFERENCE SIGNS LIST

1 Rotating device
10 Control device
11 Control board
12 Housing
20 Stepping motor
30 Control circuit
40 Drive circuit
41 Motor driver
50 Drive control unit
51 Command unit (Example of Rotation abnormality determination unit, Rotation abnormality determination restricting unit, and Dead zone determination processing unit)
52 AD converter
53 A memory
54 Pulse counter
55 Position memory
56 N counter
57 First comparator
58 X memory
59 Second comparator
60 Third comparator
61 Drive pulse output unit
62 Fourth comparator
63 Dead zone memory
64 Fifth comparator
65 Cycle counter
66 Dead zone determination processing unit
70 Actuator output shaft
71 First gear
72 Second gear
73 Third gear
74 Output gear
75 Voltage output circuit
76 FPC
77 Variable resistor
78 Voltage output line
79 Adjustment resistor
80 Position sensor (Example of Position detection circuit)
E Voltage source
Ve Voltage value of voltage source
Vo Reference voltage
Vx Adjustment voltage
Rv Resistance value of variable resistor
R1 Upper resistor
R2 Lower resistor
Rx Resistance value of adjustment resistor
A, A1, A2, A3 Position information (Example of First position information and Third position information)
B, B1, B2, B3, Ba, Bb Position information (Example of Second position information and Fourth position information)

1. A rotating device comprising:
a control circuit configured to output drive pulses of a number corresponding to a drive target included in a drive command signal from outside;
a drive circuit configured to output a drive voltage corresponding to the drive pulses;
a stepping motor rotationally driven by the drive voltage output by the drive circuit;
an output gear configured to rotate in conjunction with the rotational driving of the stepping motor; and
a voltage output circuit configured to output, to the control circuit, a voltage corresponding to a rotation position of the output gear,
wherein the voltage output circuit includes,
a position detection circuit including a variable resistor with a first end being connected to a voltage source configured to apply a predetermined voltage and a second end being connected to a ground, and a voltage output line configured to output the voltage changing as a contact position in contact with the variable resistor moves in accordance with the rotation position of the output gear, and
an adjustment resistor with a first end being connected to the voltage output line and a second end being connected to the ground and configured to adjust the voltage output from the voltage output line,
the control circuit includes a dead zone determination processing unit configured to determine the contact position of the voltage output line being located within a dead zone formed between the variable resistor and the ground in the position detection circuit, when the voltage output from the voltage output circuit has a value less than or equal to a predetermined threshold value, and to execute processing corresponding to the dead zone, when the contact position of the voltage output line is determined to be located within the dead zone, and
a resistance value of the adjustment resistor in the voltage output circuit is set to a value between a minimum value determined in a manner for a ratio of an adjustment voltage, being the voltage output from the voltage output line in a case of the voltage output circuit having the adjustment resistor, to a reference voltage output from the voltage output line in a case of the voltage output circuit not having the adjustment resistor, to become greater than or equal to a predetermined value, and a maximum value determined in a manner for noise generated on the voltage output from the voltage output line with the contact position located within the dead zone to become less than or equal to a predetermined value.

2. The rotating device according to claim 1,
wherein, when a resistance value of the variable resistor is taken as Rv, a minimum value RxMin of a resistance value Rx of the adjustment resistor is determined by an expression below,
RxMin=r×Rv/(4×(1−r)),
where r=adjustment voltage Vx/reference voltage Vo.

3. The rotating device according to claim 2,
wherein r representing a ratio of the adjustment voltage Vx to the reference voltage Vo is 0.98 or more.

4. The rotating device according to claim 1,
wherein a maximum value RxMax of the resistance value Rx of the adjustment resistor is 500 kΩ equivalent to a voltage of 250 mV or less of noise generated on the voltage, when a voltage value of the voltage source is 3.3 V.

5. The rotating device according to claim 1,
wherein, when the dead zone determination processing unit determines the contact position of the voltage output line being located within the dead zone at a power-on time,
the control circuit notifies occurrence of initial position abnormality to outside.

6. The rotating device according to claim 1,
wherein the control circuit further includes,
a rotation abnormality determination unit configured to execute abnormality determination processing for determining whether or not rotation abnormality has occurred in the output gear based on the voltage output from the voltage output circuit, and
a rotation abnormality determination restricting unit configured to restrict the determination in the rotation abnormality determination unit from being executed, when the contact position of the voltage output line is located within the dead zone.
